(19) United States
(12) Patent Application Publication
(10) Pub. No.: US 2024/0397582 A1
(43) Pub. Date: Nov. 28, 2024

(54) CERAMIC HEATER

(71) Applicant: Niterra Co., Ltd., Nagoya-shi (JP)

(72) Inventors: Shusuke SEKIYA, Nagoya-shi (JP); Kohei MITSUYA, Nagoya-shi (JP)

(21) Appl. No.: 18/671,180

(22) Filed: May 22, 2024

(30) Foreign Application Priority Data
May 26, 2023 (JP) 2023-086782
Feb. 20, 2024 (JP) 2024-024096

(51) Int. Cl. H05B 3/26

(52) U.S. Cl. CPC H05B 3/265

(57) ABSTRACT

An upper surface of a ceramic base member has a plurality of projected parts concentrically arranged in a circular pattern. A part of the plurality of projected parts is located in a circular range from 15% to 85% of an outer diameter of the ceramic base member. The average value of the coordinates of a top face of the projected parts in an up-down direction is Z (mm), a radius of the concentric circles is r (mm) and the difference between the radii of adjacent concentric circles is Δr (mm). The absolute value of Δ²Z/Δr² is not more than 10⁻⁵ (mm⁻¹) or is not more than 10⁻⁴/Δr (mm⁻¹).

### REFERENCE TO RELATED APPLICATIONS

This application claims priorities from Japanese Patent Applications No. 2023-086782, filed on May 26, 2023, and No. 2024-024096, filed on Feb. 20, 2024. The entire contents of the priority applications are incorporated herein by reference.

### BACKGROUND ART

The present disclosure relates to a ceramic heater which holds and heats a substrate such as a silicon wafer, etc.

Conventionally, there is a known ceramic heater in which a heating element is embedded inside it. In a certain known ceramic heater, a surface (heating surface) of a ceramic base member in which a substrate is placed is formed with a plurality of projected parts or projections (embossed parts) for the purpose of making a contact area with respect to the substrate small and/or a purpose of allowing gas to flow in a space defined by the substrate and the surface of the ceramic base member.

In the ceramic heater, generally, a heat spot is formed in a part of a substrate, which is placed thereon in some cases. The above-described publicly known ceramic heater attempts to suppress the formation of the heat spot by reducing the number (quantity) of the plurality of projected parts at an area overlapping with a heat spot.

### SUMMARY

In the case where a plurality of projected parts is arranged around the circumference or the upper surface of the ceramic substrate is processed in a concave or convex shape, heat spots may occur in a circumferential or arc shape due to the locating of projected parts of the ceramic base member or the cross-sectional shape of the upper surface of the ceramic base member. In some of the ceramic heaters described above, it was difficult to reduce the occurrence of such heat spots.

The present disclosure has been made in view of the above-described circumstances; an object of the present disclosure is to provide a technique for reducing the occurrence of circumferential or arc-shaped heat spots due to the arrangement of the projected parts of the ceramic base member or the cross-sectional shape of the upper surface of the ceramic base member.

According to an aspect of the present disclosure, there is provided a ceramic heater including: a ceramic heater including: a ceramic base member having a disc-shape and including an upper surface and a lower surface opposite to the upper surface in an up-down direction; and a heater embedded in the ceramic base member or located on the lower surface of the ceramic base member. The ceramic base member includes a plurality of projected parts projecting upward to be higher than the upper surface of the ceramic base member and concentrically located on the upper surface of the ceramic base member. A part of the plurality of projected parts is located in an annular range, of the upper surface of the ceramic base member, ranging from 15% to 85% of an outer diameter of the ceramic base member. The part of the plurality of projected parts is located so as to have n (n≥2) concentric circles from a center side to an outer circumference of the ceramic base member. An average value of the up-down direction coordinates of the projected parts in an (n−1)th concentric circle is Z (mm), a radius of the (n−1)th concentric circle is r (mm), a difference between a radius of an nth concentric circle and the radius of the (n−1)th concentric circle is Δr (mm), and a rate of change of Z in a radial direction is ΔZ/Δr. In the part of the plurality of projected parts, an absolute value of a rate of change of ΔZ/Δr, (Δ(ΔZ/Δr)/Δr=Δ²Z/Δr²), is not more than 10⁻⁵ (mm⁻¹) or is not more than 10⁻⁴/Δr (mm⁻¹).

As in the above-described configuration, In the above configuration, a part of the plurality of the projected parts, which is located in a circular range ranging from 15% to 85% of the outer diameter of the ceramic base member, is located so as to have n (n≥2) concentric circles from the center side of the ceramic base member to the outer circumference. The average value of the Z coordinate of the projected parts in the (n−1)th concentric circle is Z (mm), the radius of the (n−1)th concentric circle is r (mm), the difference between the radius of the nth concentric circle and that of the (n−1)th concentric circle is Δr (mm), and the rate of change of Z in the radial direction is ΔZ/Δr. The absolute value of Δ²Z/(Δr)² is not more than 10⁻⁵ or not more than 10⁻⁴/Δr. When such a relationship is satisfied, the occurrence of circumferential or arc-shaped heat spots is reduced.

### BRIEF DESCRIPTION OF DRAWINGS

FIG. 1 is a perspective view of a ceramic heater 100.

FIG. 2 is a view for explaining a schematic configuration of the ceramic heater 100.

FIGS. 3A to 3C depict schematic illustrations of the cross section of the ceramic base member 110.

FIGS. 4A and 4B depict schematic illustrations of the cross section of the tops of the plurality of projected parts 156.

FIG. 5 is a schematic illustration of the electrode 120.

FIG. 6 depicts a schematic illustration of the heater electrode 122.

FIGS. 7A to 7E depict a flow of a method of producing the ceramic base member 110.

FIGS. 8A to 8D depict a flow of another method of producing the ceramic base member 110.

FIG. 9 depicts a table summarizing the results of Example 1.

FIG. 10 depicts a table summarizing the results of Example 2.

FIG. 11 depicts a table summarizing the results of Example 3.

FIG. 12 depicts a table summarizing the results of Example 4.

FIG. 13 depicts a table summarizing the results of Comparative Example 1.

FIG. 14 depicts a table summarizing the results of Comparative Example 2.

### DESCRIPTION

### Ceramic Heater 100

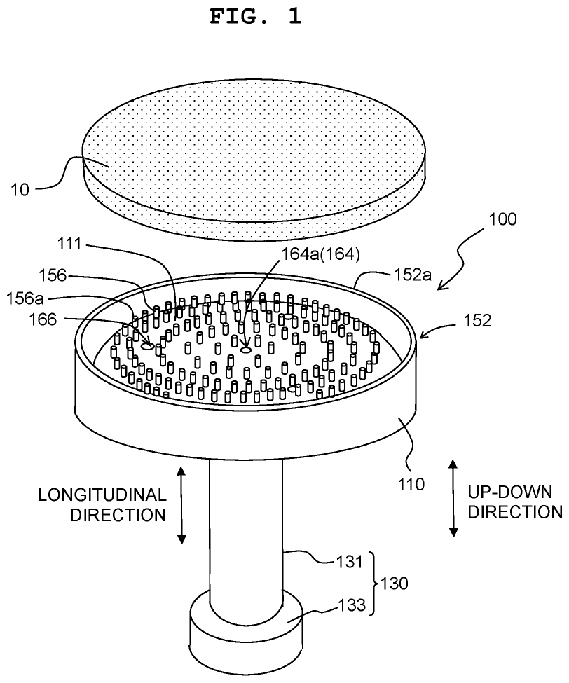

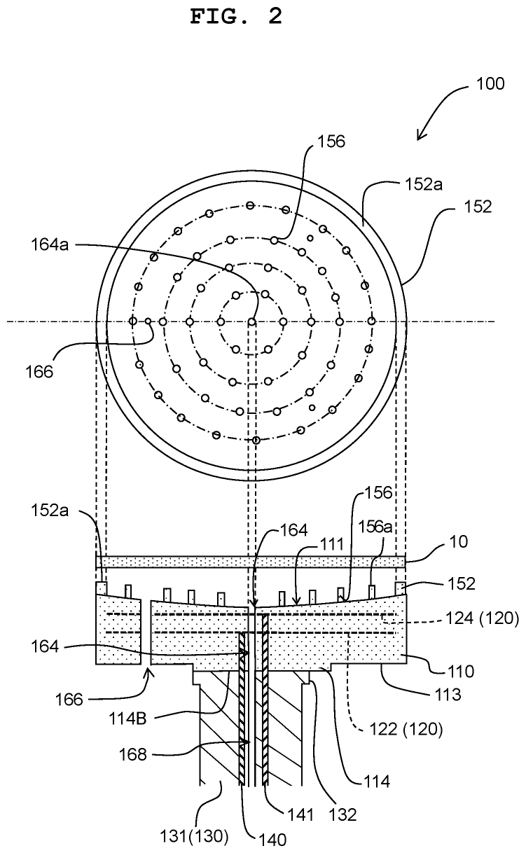

A ceramic heater 100, according to an embodiment of the present disclosure, will be explained, with reference to FIGS. 1 and 2. The ceramic heater 100, according to the present embodiment, is used, for example, for holding and heating semiconductor wafers (hereinafter referred simply to as a “wafer 10”) such as a silicon wafer, etc., in the inside of a semiconductor-producing apparatus. Note that in the following explanation, an up-down direction is defined, with a state that the ceramic heater 100 is installed usably (a state depicted in FIG. 2) as the reference. As depicted in FIG. 2, the ceramic heater 100, according to the present embodiment, includes a ceramic base member 110, an electrode 120, and feeding lines 140 and 141.

The ceramic base member 110 is a member having the shape of a circular plate with a diameter of 12 inches (approximately 300 mm); a wafer 10 is placed on the ceramic base member 110. The ceramic base member 110 can be formed, for example, of a ceramic sintered body of aluminum nitride, silicon carbide, alumina, silicon nitride, etc. Note that in FIG. 2, the wafer 10 and the ceramic base member 110 are illustrated as being separated from each other so that the drawing can be easily seen. As depicted in FIG. 1, a projected part 152 having an annular (circular) shape (hereinafter referred to simply as an “annular projected part 152”) and a plurality of projected parts 156 are provided on an upper surface 111 of the ceramic base member 110. Note that in FIG. 2, the number (quantity) of the plurality of projected parts 156 is reduced so that the drawing is easily seen. Further, as depicted in FIG. 1, an opening 164a of a gas channel 164 (see FIG. 2) is formed in the center of the ceramic base member 110. The diameter of the opening 164a is 5 mm. Further, locations obtained by equally partitioning or dividing a circle with a radius of 80 mm into three parts are provided, respectively, with lift-pin holes 166. The diameter of each of the lift-pin holes 166 is 5 mm.

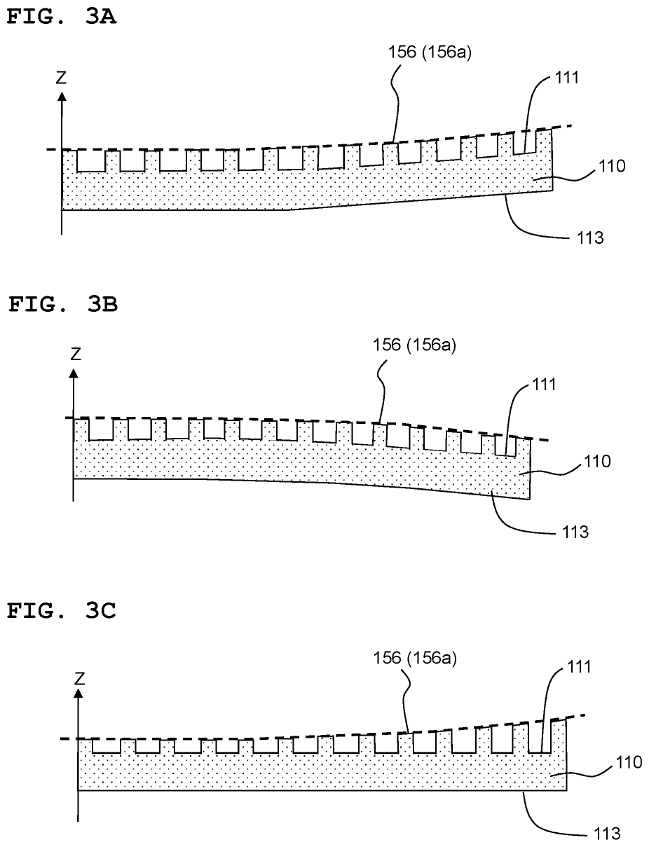

The upper surface 111 of the ceramic base member 110 of the present embodiment has a concave shape that is convex below or a convex shape that is convex above. For example, as depicted in FIG. 2, the upper surface 111 of the ceramic base member 110 may have a concave shape, and the lower surface 113 may be a horizontal plane (perpendicular to the up-down direction). As depicted in FIG. 3A, the upper surface 111 and the lower surface 113 of the ceramic base member 110 may be parallel, and both have a concave shape. As depicted in FIG. 3B, the upper surface 111 and the lower surface 113 of the ceramic base member 110 may be parallel, and both have a convex shape. Alternatively, if the enveloping surfaces of the top face 156a of the plurality of projected parts 156 described below have a concave shape (see FIG. 3C) or a convex shape (not depicted), the upper surface 111 and lower surface 113 of the ceramic base member 110 may both be horizontal plane (vertical to the up-down direction).

As depicted in FIGS. 1 and 2, the annular projected part 152 is a projected part having an annular (circular ring) shape and is arranged in the outer peripheral part (outer edge part) of the upper surface 111 of the ceramic base member 110 and projects upward from (to be higher than) the upper surface 111. As depicted in FIG. 2, in a case where the wafer 10 is placed on the ceramic base member 110, a top face 152a of the annular projected part 152 makes contact with a lower surface of the water 10. Namely, the annular projected part 152 is arranged at a position at which the annular projected part 152 overlaps with the wafer 10 in the up-down direction in the case that the wafer 10 is placed on the ceramic base member 110.

The plurality of project parts 156 is provided on the upper surface 111 of the ceramic base member 110 at a location on the inside of the annular projected part 152. The plurality of project parts 156 is arranged coaxially (in concentric circles). The shape of a top face 156a of each of the plurality of projected parts 156 is circular. In this specification, the top face 156a refers to the upper-end surface of each of the projected parts 156. The location and/or the number of the plurality of projected parts 156 may be set appropriately according to the application, action, and function.

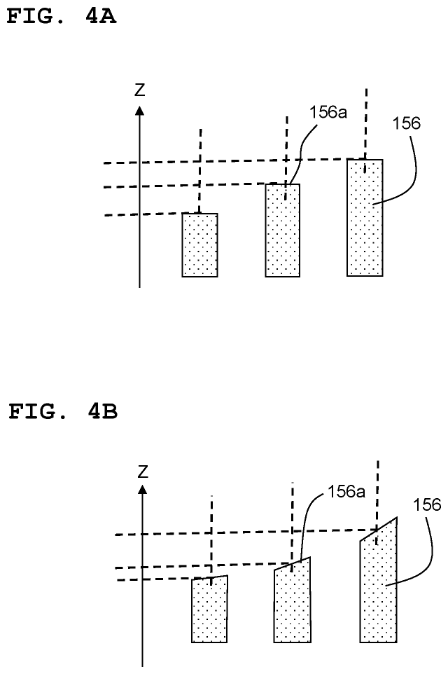

The top face 156a of the plurality of projected parts 156 may be a horizontal surface (see FIG. 4A) or may not be a horizontal surface (see FIG. 4B). From the viewpoint of easing contact pressure with the wafer 10 and reducing heat spots, it is preferable for the top surface 156a of the plurality of projected parts 156 be a curved surface. In this specification, the height of the annular projected part 152 and the height of the plurality of projected parts 156 are defined as the length in the up-down direction from the upper surface 111 of the ceramic base member 110. In this embodiment, the height of the plurality of projected parts 156 and the height of the annular projected part 152 can both be in the range of 5 μm to 2 mm.

The width of the top face 152a of the annular projected part 152 is preferably a constant (given) width and may be made in a range of 0.1 mm to 10 mm. A center line average roughness Ra in the top face 152a of the annular projected part 152 can be made to be 1.6 μm or less. Note that the center line average roughness Ra represents unevenness or roughness (concave parts and convex parts) in a surface by an average of the absolute values of deviations from the center line thereof. Similarly, a center line average roughness Ra in the top face 156a of the plurality of projected parts 156 can be made to be 1.6 μm or less. Note that the center line average roughness Ra in each of the top face 152a of the annular projected part 152 and the top face 156a of the plurality of projected parts 156 is preferably 0.4 μm or less, more preferably 0.2 μm or less and further more preferably 0.1 μm or less.

A clearance (spacing distance) between respective projected parts of the plurality of projected parts 156 can be made in a range of 1.5 mm to 30 mm. When the plurality of projected parts 156 is arranged concentrically, the separation distance in the radial direction should be 5 mm to 20 mm, and the separation distance in the circumferential direction should also be 5 mm to 20 mm.

As described above, the opening 164a of the gas channel 164 is opened at the substantial center in the upper surface 111 (see FIG. 2). The gas channel 164 includes the opening 164a and is formed inside the ceramic base member 110. In the present embodiment, the gas channel 164 extends downward from the opening 164a. The gas channel 164 can be used as a channel for supplying gas to a space (gap) defined by the upper surface 111 of the ceramic base member 110 and the lower surface of the wafer 10. For example, it is possible, via the gas channel 164, to supply a heat transfer gas for heat transfer between the wafer 10 and the ceramic base member 110. As heat transfer gas, for example, it is possible to use an inert gas such as helium, argon, nitrogen gas, etc. The heat transfer gas is supplied via the gas channel 164 at a pressure which is set within a range of 100 Pa to 40000 Pa. Further, in a case where a process gas enters into a gap in the inside of the annular projected part 152, from a gap between the top face 152a of the annular projected part 152 and the lower surface of the wafer 10, it is possible to exhaust (discharge) the process gas via the gas channel 164. In this situation, by adjusting the exhaust pressure, it is possible to adjust a differential pressure between the pressure at the outside of the gap and the pressure at the inside of the gap. With this, it is possible to attract the wafer 10, by suction, toward the upper surface 111 of the ceramic base member 110.

As depicted in FIG. 2, the electrode 120 is embedded in the inside of the ceramic base member 110. The electrode 120 includes a heater electrode 122 and an electrostatic attraction electrode 124. The electrostatic attraction electrode 124 is embedded in the inside of the ceramic base member, at a location above the heater electrode 122.

As depicted in FIG. 5, the electrostatic attraction electrode 124 is arranged such that two semi-circular electrodes 124a and 124b face each other at a predetermined spacing distance, and has, as a whole, a substantially circular shape. In the present embodiment, the outer diameter of the electrostatic attraction electrode 124 is 292 mm. By applying a predetermined voltage (for example, ±500V) to each of the electrodes 124a and the electrode 124b, it is possible to attract the wafer 10 by the electrostatic suction.

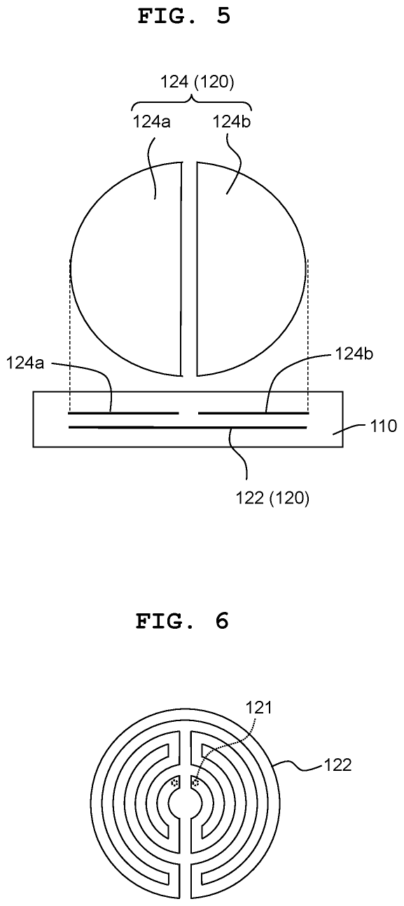

As depicted in FIG. 6, the heater electrode 122 is a metallic mesh or foil that is cut into the shape of a belt or band. The outer diameter of the heater electrode 122 is 298 mm. The heater electrode 122 is not exposed from the side surface of the ceramic base member 110. A terminal part 121, which is connected to the feeding line 140 (see FIG. 2), is provided at a substantially central part of the heater electrode 122. The heater electrode 122 is formed of a heat-resisting metal (high melting point metal) such as, for example, a foil including tungsten (W), molybdenum (Mo), or an alloy including the molybdenum and/or the tungsten, or a mesh which is obtained by weaving a wire including tungsten (W), molybdenum (Mo) or an alloy including the molybdenum and/or the tungsten; etc. It is preferred that the purity of each of the tungsten and the molybdenum is 99% or more. The thickness of the heater electrode 122 is 0.15 mm or less. Note that from the viewpoint of making the resistance value of the heater electrode 122 high to thereby reduce the current consumption of the ceramic heater 100, it is preferred that the wire diameter of the wire is made to be 0.1 mm or less and that the thickness of the heater electrode 122 is made to be 0.1 mm or less, except for an intersection point of the wire. Further, the width of the heater electrode 122, which is cut into the shape of the band, is preferably in a range of 2.5 mm to 20 mm, more preferably in a range of 5 mm to 15 mm. In the present embodiment, although the heater electrode 122 is cut in the shape depicted in FIG. 4, the shape of the heater electrode 122 is not limited to this and may be changed as appropriate. Note that it is allowable that a plasma electrode configured to generate a plasma at a location above the ceramic base member 110 is embedded in the inside of the ceramic base member 110, in addition to the heater electrode 122 or instead of the heater electrode 122.

As depicted in FIG. 2, the feeding line 140 configured to supply an electric power to the heater electrode 122 and the feeding line 141 configured to supply the electric power to the electrostatic attraction electrode 124 are arranged in the ceramic heater 100. Note that in FIG. 2, although only one of the feeding lines 140 and one of the feeding lines 141 are depicted, a plurality of feeding lines 140 and a plurality of feeding lines 141 are actually arranged. An upper end of the feeding line 140 is electrically connected to the terminal part 121 (see FIG. 4) arranged in the center of the heater electrode 122. The feeding line 140 is connected to a non-illustrated power source for the heater. With this, the electric power is supplied to the heater electrode 122 via the feeding line 140. Similarly, the electric power is supplied to the electrostatic attraction electrode 124 via the feeding line 141.

Next, an explanation of the method of producing the ceramic heater 100 will be given. In the following, a case in which the ceramic base member 110 is formed of aluminum nitride will be explained as an example.

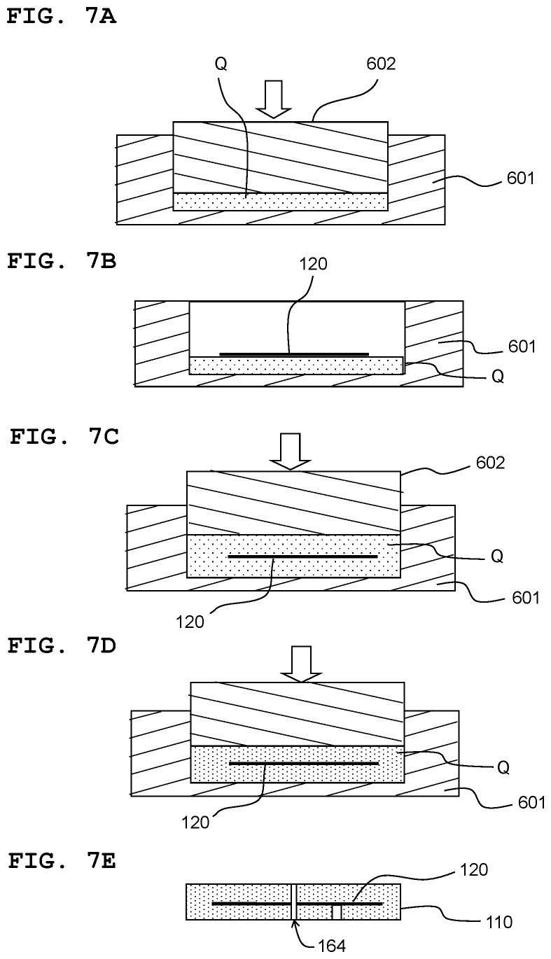

First, a method of producing the ceramic base member 110 will be explained. Note that for simplifying the explanation, it is presumed that only the heater electrode 122 is embedded, as the electrode 120, on the inside of the ceramic base member 111. As depicted in FIG. 7A, granulated powder Q, which contains aluminum nitride (AlN) powder as a main component thereof, is charged to a bottomed mold 601 made of carbon and is subjected to a temporary pressing with a punch 602. Note that it is preferred that 5 wt % or less of the sintering agent (for example, Y₂O₃) is included in the granulated powder Q. Next, as depicted in FIG. 7B, the heater electrode 122, which is cut to a predetermined shape, is arranged on the temporarily pressed granulated powder Q. Note that the heater electrode 122 is arranged to be parallel to a plane orthogonal to a pressing direction (the bottom surface of the bottomed mold 601). In this situation, it is allowable to embed a pellet formed of tungsten (W) or molybdenum (Mo) at a position of the terminal 121 (see FIG. 6) of the heater electrode 122.

As depicted in FIG. 7C, the granulated power Q is further charged to the bottomed mold 601 so as to cover the heater electrode 122 and is subjected to molding while being pressed with the punch 602. Next, as depicted in FIG. 7D, the baking is performed for the granulated power Q in which the heater electrode 122 is embedded in a state where the granulated power Q is pressed. The pressure applied during the baking is preferably 1 MPa or more. Further, it is preferred that the baking is performed at a temperature which is 1800° C. or more. Next, as depicted in FIG. 7E, the blind hole driving process is performed up to a location of the heater electrode 122 so as to form the terminal 121. Note that in a case where the pellet is embedded, the blind hole driving process can be performed up to the location of the pellet. Further, a through hole, which becomes a part of gas channel 164, is formed. With this, it is possible to produce a ceramic base member 110 in which the gas channel 164 is formed on the inside thereof. In this case, it is preferred that a predetermined opening is provided in advance on the heater electrode 122 so that the heater electrode 122 is not exposed from the gas channel 164.

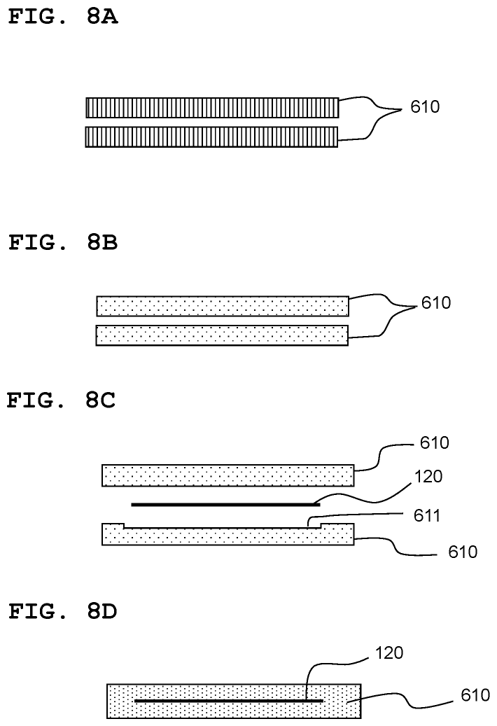

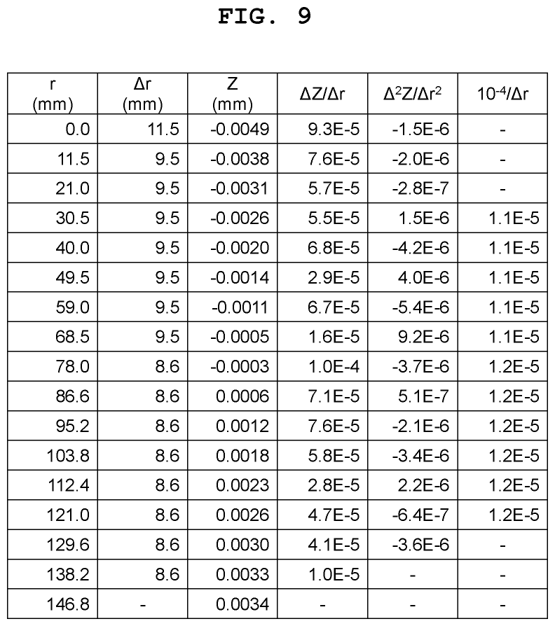

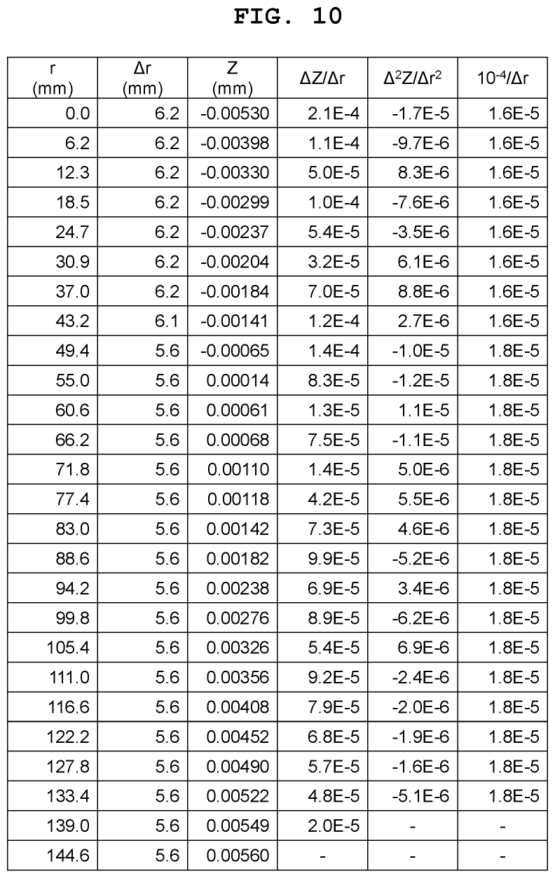

Note that the ceramic base member 110 can also be formed by the following method. As depicted in FIG. 8A, a binder is added to the granulated powder Q of the aluminum nitride so as to perform the CIP (Cold Isostatic Press) molding followed by being processed to have a disc shape, thereby producing molded bodies (compacts) 610 of the aluminum nitride. Next, as depicted in FIG. 8B, a degreasing process is performed for the molded bodies 610 so as to remove the binder.

As depicted in FIG. 8C, a recessed part 611 for embedding the heater electrode 122 is formed in a degreased molded body 610 of the degreased molded bodies 610. The heater electrode 122 is arranged in the recessed part 611 formed in the molded body 610, and another molded body 610 of the molded bodies 610 is stacked on the molded body 610. It is also allowable to form the recessed part 611 in advance in the molded body 610. Next, as depicted in FIG. 8D, the molded bodies 610 which are stacked so as to sandwich the heater electrode 122 therebetween is subjected to the baking in a state that the stacked molded bodies 610 are pressed, thereby preparing a baked body. It is preferred that the pressure applied during the baking is 1 MPa or more. Further, it is preferred that the basking is performed at a temperature which is 1800° C. or more. Since the steps after producing the baked boy are similar to the steps described above, any explanation therefor, will be omitted.

Grinding is performed with respect to the upper surface 111 of the ceramic base member 110 formed in such a manner, and a lapping process (minor surface polishing process) is performed. Further, by performing a sandblasting process with respect to the upper surface 111, the plurality of projected parts 156 and the annular projected part 152 are formed in the upper surface 111. In this situation, the process is performed so that the height of the plurality of projected parts 156 is the same. Further, the top face 152a of the annular projected part 152 is processed to have a predetermined shape. Note that although the sandblasting process is suitable as a method of forming the processing method for forming the plurality of projected parts 156 and the annular projected part 152, it is allowable to use another processing method different from the sandblasting process.

### EXAMPLES

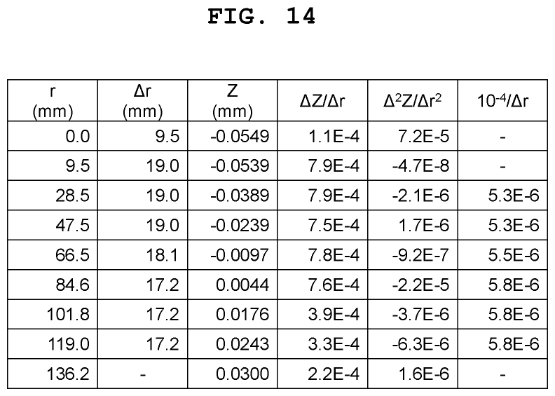

The present disclosure will be further described using Examples 1 to 4 below. The present disclosure is not limited to the examples described below. FIGS. 9 to 12 depict tables indicating the results of Examples 1 to 4. FIGS. 13 and 14 depict tables indicating the results of Comparative Examples 1 and 2.

### Example 1

A ceramic heater 100 (see FIG. 2) of Example 1 is described. In Example 1, the ceramic base member 110 with a diameter of 300 mm and a thickness of 25 mm was prepared by the above-mentioned producing method using aluminum nitride (AlN) with a sintering aid (Y₂O₃) added at 5 wt %. The ceramic base member 110 of Example 1 had a convex downward curved shape (see FIG. 3A). In the ceramic heater 100 of Example 1, the electrostatic attraction electrode 124 described above was not embedded, and the heater electrode 122 of the shape depicted in FIG. 6 was embedded in the ceramic base member 110.

The opening 164a for the gas channel 164 (see FIG. 2) was provided at the center of the ceramic base member 110. The diameter of the opening 164a was 4 mm.

The annular projected parts 152, with an inner diameter of 296 mm, an outer diameter of 300 mm, and a width of 2 mm, were formed on the upper surface 111 of the ceramic base member 110. The height of the annular projected part 152 was 150 μm. In addition, the plurality of projected parts 156 of cylindrical shape were formed on the upper surface 111 of the ceramic base member 110. The shape of the top face 156a of the plurality of projected parts 156 was circular with a diameter of 3 mm. The height of the plurality of projected parts 156 was 150 μm. The plurality of projected parts 156 was arranged in concentric circles with diameters ranging from 20 mm to 140 mm, 10 mm apart, and evenly spaced within a range of 8 to 12 mm. The centerline average roughness Ra of the top face 152a of the annular projected part 152 and the top face 156a of the plurality of projected parts 156 were both 0.4 μm.

The probe of a three-dimensional measuring instrument was attached to the top face 156a of the plurality of projected parts 156 to measure the coordinate values of the center of gravity of the top surface 152a in the radial direction and in the up-down direction. Then, for the top face 156a of the projected parts 156 located on the same concentric circle, the average of the coordinate values in the up-down direction was taken, and the average value Z of the coordinate values in the up-down direction corresponding to this concentric circle was calculated. In this case, it is preferable to take an average of 8 or more points. For the top faces 156a of the projected parts 156 located on the same concentric circle, the distances between the center of gravity of the top faces 156a and the center of the ceramic base member 110 were determined, and the average value was used as the radius r of the concentric circle. The difference between the radius r of one concentric circle and the radius of the adjacent concentric circles outside of it was Δr. Based on this, the second differentiation of the mean value Z (mm) of the projected parts 156 with respect to the radius r (mm) (Δ²Z/Δr²) (unit: mm⁻¹) and value 10⁻⁴/Δr (unit: mm⁻¹) were calculated. In this document, such a measurement is referred to as the measurement of the cross-sectional curve of the mounting surface. When the centerline average roughness Ra of the top face 156a is 0.2 μm or less, the measurement of the cross-sectional curve of the mounting surface can also be performed by laser interferometry.

Although not employed in Example 1, a super flat wafer (TTV=0.1 μm or less is preferred) can be placed on the ceramic heater 100, and the r-coordinate and Z-coordinate on a radial line passing through the center of the surface side of the wafer can be measured. A three-dimensional measuring instrument or a laser interferometer can be used to measure the cross-sectional curves of the mounting surface. In this case, the interval between the r-coordinates to be measured is Δr.

FIG. 9 depicts a table summarizing the measurement results of the cross-sectional curves of the mounting surface for the ceramic heater 100 of Example 1. Note that, in Example 1, the outer diameter of the ceramic base member 110 is the same as the outer diameter of the annular projected part 152. As can be seen from the table in FIG. 9, within a circular range of 15% to 85% of the outer diameter of the ceramic base member 110 (in Example 1, the outer diameter of the annular projected part 152 is 300 mm, so r=25 mm to 125 mm), Δ²Z/Δr² was not more than 10⁻⁴/Δr (mm⁻¹) and was not more than 10⁻⁵ (mm⁻¹).

A silicon wafer of 300 mm in diameter for temperature evaluation was placed on the ceramic heater 100 in a vacuum chamber. The gas pressure in the vacuum chamber was then reduced to 200 Torr in an Δr atmosphere, the gas channel 164 was connected to an unshown exhaust system, and the exhaust system outlet pressure was set to 50 Torr. As a result, the silicon wafer was vacuumed by the differential pressure (150 Torr). The temperature distribution of the silicon wafer during vacuum suction was evaluated according to the following procedure.

An unshown external power supply was connected to the heater electrode 122 of the ceramic heater 100, and the output power of the external power supply was adjusted so that the temperature of the upper surface of the silicon wafer was 500° C. under steady-state conditions. The temperature distribution of the silicon wafer for temperature evaluation was then measured with an infrared camera. The temperature contour diagram (color bar) of the infrared camera was set so that the temperature range was 3° C. or less, and the presence of arc-shaped heat spots was visually checked on the temperature contour diagram. If heat spots were observed, the temperature distribution in the radial direction passing through the center of the silicon wafer and through the heat spots was measured. If no heat spot was observed, the temperature distribution in any radial direction was measured, and the deviation between the target value and the measured value was measured. The temperature distribution was measured within a circular range of 15% to 85% of the outer diameter of the ceramic base member 110 (in Example 1, the outer diameter of the annular projected part 152 is 300 mm, so the range is r=25 mm to 125 mm). A heat spot was judged to be present if a temperature difference of 1.0° C. or more occurred per 50 mm of arbitrary distance in the radial direction. In other words, a heat spot was judged to be present when the absolute value of the following expression is 0.5° C. or more in the range of any r1 to r2 (the separation distance between r1 and r2 is 50 mm), where “measured value at any r−(measured value at r1+measured value at r2)/2”.

In Example 1, no heat spots were observed.

### Example 2

In Example 2, the radial pitch of the plurality of projected parts 156 has been changed from that of the ceramic heater 100 of Example 1. The ceramic base member 110 of Example 2 had a convex downward curved shape (see FIG. 3A).

The ceramic heater 100, having such a shape, was installed in the vacuum chamber, and the silicon wafer for temperature evaluation, similar to Example 1, was placed on the ceramic heater 100. Then, the temperature distribution of the silicon wafer was evaluated by measuring the cross-sectional curves of the mounting surface in the same manner as in Example 1.

FIG. 10 depicts a table summarizing the measurement results for the ceramic heater 100 of Example 2. As can be seen from the table in FIG. 10, the absolute value of Δ²Z/Δr² was greater than 10⁻⁵ (mm⁻¹) but not more than 10⁻⁴/Δr (mm⁻¹) within the circular range of 15% to 85% of the outer diameter of the ceramic base member 110. In Example 2, no heat spots were observed.

### Example 3

In Example 3, the radial pitch of the plurality of projected parts 156 has been changed from the ceramic heater 100 of Example 1. The ceramic base member 110 of Example 3 had a convex downward curved shape (see FIG. 3A).

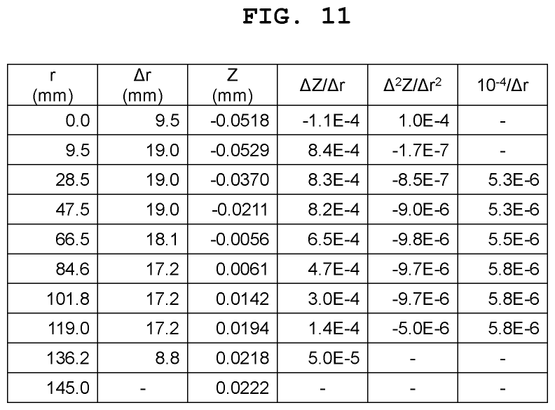

The ceramic heater 100, having such a shape, was installed in the vacuum chamber, and the silicon wafer for temperature evaluation, similar to Example 1, was placed on the ceramic heater 100. Then, the temperature distribution of the silicon wafer was evaluated by measuring the cross-sectional curves of the mounting surface in the same manner as in Example 1. FIG. 11 depicts a table summarizing the measurement results for the ceramic heater 100 of Example 3. As can be seen from the table in FIG. 11, the absolute value of Δ²Z/Δr² was greater than 10⁻⁴/Δr (mm⁻¹) but not more than 10⁻⁵ (mm⁻¹) within the circular range of 15% to 85% of the outer diameter of the ceramic base member 110. In Example 3, no heat spots were observed.

### Example 4

In Example 4, the radial pitch of the plurality of projected parts 156 has been changed from the ceramic heater 100 of Example 1. The ceramic base member 110 of Example 4 had an upwardly convex curved shape (see FIG. 3B).

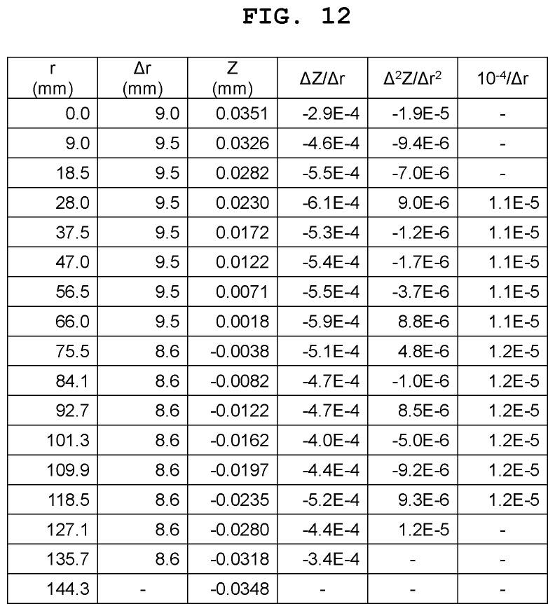

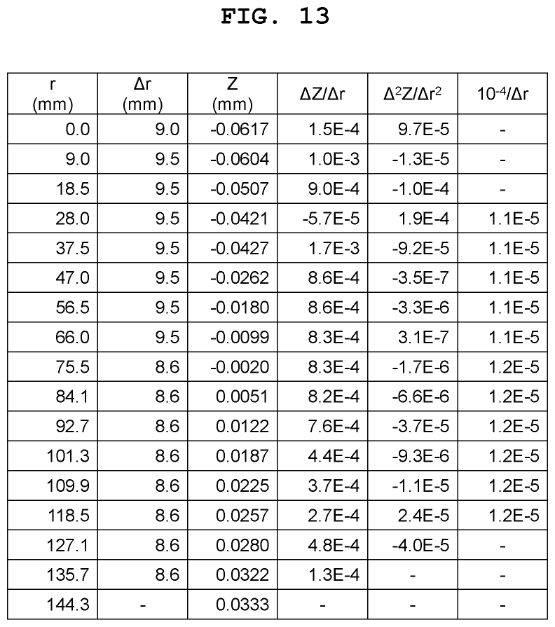

The ceramic heater 100, having such a shape, was installed in the vacuum chamber, and the silicon wafer for temperature evaluation, similar to Example 1, was placed on the ceramic heater 100. Then, the temperature distribution of the silicon wafer was evaluated by measuring the cross-sectional curves of the mounting surface in the same manner as in Example 1. FIG. 12 depicts a table summarizing the measurement results for the ceramic heater 100 of Example 4. As can be seen from the table in FIG. 12, the absolute value of Δ²Z/Δr² was not more than 10⁻⁴/Δr (mm⁻¹) and not more than 10⁻⁵ (mm⁻¹) within the circular range of 15% to 85% of the outer diameter of the ceramic base member 110. In Example 4, no heat spots were observed.

### Comparative Example 1

The ceramic heater 100 of Comparative Example 1 had the same radial pitch of the plurality of projected parts 156 as the ceramic heater 100 of Example 4. The ceramic base member 110 of Comparative Example 1 had a convex downward curved shape (see FIG. 3A).

The ceramic heater 100, having such a shape, was installed in the vacuum chamber, and the silicon wafer for temperature evaluation, similar to Example 1, was placed on the ceramic heater 100. Then, the temperature distribution of the silicon wafer was evaluated by measuring the cross-sectional curves of the mounting surface in the same manner as in Example 1. FIG. 13 depicts a table summarizing the measurement results for the ceramic heater 100 of Comparative Example 1. As can be seen from the table in FIG. 13, within the circular range of 15% to 85% of the outer diameter of the ceramic base member 110, there were locations where the absolute value of Δ²Z/Δr² was greater than 10⁻⁴/Δr (mm⁻¹) and 10⁻⁵ (mm⁻¹), and heat spots were observed in the vicinity of the locations.

### Comparative Example 2

In Comparative Example 2, the radial pitch of the plurality of projected parts 156 has been changed from the ceramic heater 100 of Example 1. The ceramic base member 110 of Comparative Example 2 had a convex downward curved shape (see FIG. 3A).

The ceramic heater 100, having such a shape, was installed in the vacuum chamber, and the silicon wafer for temperature evaluation, similar to Example 1, was placed on the ceramic heater 100. Then, the temperature distribution of the silicon wafer was evaluated by measuring the cross-sectional curves of the mounting surface in the same manner as in Example 1. FIG. 14 depicts a table summarizing the measurement results for the ceramic heater 100 of Comparative Example 2. As can be seen from the table in FIG. 14, within the circular range of 15% to 85% of the outer diameter of the ceramic base member 110, there were locations where the absolute value of Δ²Z/Δr² was greater than 10⁻⁴/Δr (mm⁻¹) and 10⁻⁵ (mm⁻¹), and heat spots were observed in the vicinity of the locations.

### Technical Effects of the Embodiments

In the above embodiments and Examples 1 to 4, the ceramic heater 100 has the disc-shaped ceramic base member 110 and the heater electrode 122 embedded in the ceramic base member 110. The upper surface 111 of the ceramic base member 110 has a plurality of projected parts 156, which are concentrically located in a circular pattern. The following relationship holds for some of the plurality of projected parts 156 provided on the upper surface 111 of the ceramic base member 110 in the circular range from 15% to 85% of the outer diameter of the ceramic base member 110. Note that the circular range of 15% to 85% of the outer diameter of the ceramic base member 110 is defined as the circular range formed by a first virtual circle having an outer diameter that is 15% of the outer diameter of the ceramic base member 110 and a second virtual circle having an outer diameter that is 85% of the outer diameter of the ceramic base member 110. It is difficult to determine the deviation of the height of the projected parts 156 near the center and near the outer diameter of the ceramic base member 110 because the projected parts 156 are concentrically spaced in the radial direction. Accordingly, the above ranges are defined to determine the height deviation of the projected parts 156. When the annular projected part 152 is provided on the upper surface 111 of the ceramic base member 110, the outer diameter of the ceramic base member 110 can be defined as the outer diameter of the annular projected part 152.

A part of the plurality of the projected parts 156 provided in the above circular range is arranged so as to have n (n≥2) concentric circles from the center side of the ceramic base member 110 to the outer circumference. The average value of the coordinates of the up-down direction of the projected parts 156 in the (n−1)th concentric circle is Z (mm), the radius of the (n−1)th concentric circle is r (mm), and the difference between the radius of the nth concentric circle and the radius of the (n−1)th concentric circle is Δr (mm). The absolute value of Δ²Z/(Δr)² is not more than 10⁻⁵ (mm⁻¹) or not more than 10⁻⁴/Δr (mm⁻¹). Here, ΔZ/Δr means the rate of change of the average Z (mm) of the Z coordinate of the projected parts 156 in the radial direction. Further, Δ²Z/(Δr)² means the rate of change of (ΔZ/Δr).

According to Examples 1 to 4, no heat spots were observed in the above circular range when the absolute value of Δ²Z/(Δr)² is not more than 10⁻⁵ (mm⁻¹) or not more than 10⁻⁴/Δr (mm⁻¹) In contrast, according to Comparative Examples 1 and 2, heat spots were observed near locations where the absolute value of Δ²Z/(Δr)² was greater than 10⁻⁵ (mm⁻¹) and greater than 10⁻⁴/Δr (mm⁻¹).

According to the inventors' findings, the temperature distribution of the wafer 10 is likely to be centrosymmetrically M-shaped and W-shaped, especially in the center of the radial direction (e.g., the range from 50 mm in diameter (25 mm radius) to 250 mm in diameter (125 mm radius) for the substrate size of 300 mm in diameter). Such a range corresponds to the circular range described above. The substrate mounting surface is composed of the top faces 156a of the plurality of projected parts 156, and in some cases, the substrate mounting surface is an envelope of the top face 156a. In the cross-sectional shape through the center of the substrate mounting surface, if there is a point where a sudden change occurs in the up-down direction, the contact pressure between the corresponding projected part 156 and the wafer 10 increases at that point. As a result, excessive heat is transferred, and heat spots are considered to occur in an arc shape. In Examples 1-4, the absolute value of Δ²Z/(Δr)² can be set to 10⁻⁵ (mm⁻¹) or less, or 10⁻⁴/Δr (mm⁻¹) or less, where (ΔZ/Δr) is the rate of change of the average value Z (mm) of the Z coordinate of the projected parts 156 in the radial direction, and Δ²Z/(Δr)² is the rate of change of (ΔZ/Δr). In this case, a rapid change in the substrate mounting surface (envelope of the top face 156a) in the up-down direction could be suppressed. This is believed to have suppressed the occurrence of heat spots and equalized the heat of the wafer 10.

### Modifications

The above-described embodiments are examples only and can be modified as needed. For example, the shape and dimensions of the ceramic base member 110 are not limited to those of the above-described embodiments but can be changed as needed. The height, width, and other dimensions of the annular projected part 152, the shape of the top face 152a of the annular projected part 152, and the magnitude of the centerline average roughness Ra of the top face 152a can be changed as needed. The height of the plurality of projected parts 156, the shape of the top face 156a, and the magnitude of the centerline average roughness Ra of the top face 156a can be changed as needed. For example, the shape of the top face 156a of the plurality of projected parts 156 need not be circular, and can be a suitable shape, such as a square.

In the above-described embodiment, the molybdenum, the tungsten, or an alloy including the molybdenum and/or the tungsten is used as the material forming the heater electrode 122. The present disclosure, however, is not limited to such an aspect. For example, it is allowable to use a metal or an alloy different from the molybdenum and the tungsten. Further, the electrode 120 includes the heater electrode 122 as the heating element. It is not necessarily indispensable, however, that the electrode 120 includes the heater electrode 122 as the heating element; it is allowable, for example, the electrode 120 includes a high frequency electrode.

In the above-described embodiment, although the ceramic heater 100 includes the heater electrode 120 embedded in the ceramic base member 110, the present disclosure is not limited to such an aspect; it is allowable that the heater electrode 120 is not embedded in the ceramic base member 110. For example, it is also allowable that the heater electrode or a high-frequency electrode as the heating element is adhered to a rear surface 113 (see FIG. 2) of the ceramic base member 110.

In the foregoing, although the explanation has been given by using the embodiment and the modifications thereof of the present disclosure, the technical scope of the present disclosure is not limited to the scope or range of the above-described description. It is apparent to a person skilled in the art that various changes or improvements can be made to the above-described embodiment. It is also apparent from the description of the claims to the person skilled in the art that an aspect obtained by adding such a change or improvement is also included in the technical scope of the present disclosure.

The order of execution of the respective processes in the production method indicated in the specification and in the drawings can be executed in an arbitrary order unless the order is clearly described and/or unless the output of a preceding process is used in a succeeding process. Even in a case where the explanation is given by using, for the sake of convenience, the terms such as “at first,” “first,” “next,” “then,” etc., it is not meant that it is necessarily indispensable that the respective processes are executed in this order.

What is claimed is:

1. A ceramic heater comprising:
a ceramic base member having a disc-shape and including an upper surface and a lower surface opposite to the upper surface in an up-down direction; and
a heater embedded in the ceramic base member or located on the lower surface of the ceramic base member, wherein
the ceramic base member includes a plurality of projected parts projecting upward to be higher than the upper surface of the ceramic base member and concentrically located on the upper surface of the ceramic base member,
a part of the plurality of projected parts is located in an annular range, of the upper surface of the ceramic base member, ranging from 15% to 85% of an outer diameter of the ceramic base member,
the part of the plurality of projected parts is located so as to have n (n≥2) concentric circles from a center side to an outer circumference of the ceramic base member,
an average value of the up-down direction coordinates of the projected parts in an (n−1)th concentric circle is Z (mm), a radius of the (n−1)th concentric circle is r (mm), a difference between a radius of an nth concentric circle and the radius of the (n−1)th concentric circle is Δr (mm), and a rate of change of Z in a radial direction is ΔZ/Δr,
in the part of the plurality of projected parts, an absolute value of a rate of change of ΔZ/Δr, (Δ(ΔZ/Δr)/Δr=Δ²Z/Δr²), is not more than 10⁻⁵ (mm⁻¹) or is not more than 10⁻⁴/Δr (mm⁻¹).
